(19) United States
(12) Patent Application Publication
(10) Pub. No.: US 2019/0228827 A1
(43) Pub. Date: Jul. 25, 2019

(54) Dynamic Management of a NAND Flash Memory

(71) Applicant: Goke US Research Laboratory, Santa Clara, CA (US)

(72) Inventors: Jia-Jyun Syu, Santa Clara, CA (US); Bo-Shian Hsu, Santa Clara, CA (US); Po-Chien Chang, Santa Clara, CA (US)

(21) Appl. No.: 15/877,589

(22) Filed: Jan. 23, 2018

(51) Int. Cl. G11C 16/34; G06F 3/06; G06F 12/0811; G06F 12/02

(52) U.S. Cl. CPC G11C 16/3495; G06F 3/0616; G06F 12/0811; G06F 2212/2022; G06F 3/0659; G06F 3/0679; G06F 12/0246

(57) ABSTRACT

A method for dynamically managing a NAND flash memory includes the step of receiving a write command from a host. The write command includes data to be stored in the NAND flash memory. Then, it is determined whether if the NAND flash memory has passed an early phase of its life of service. A first portion of the NAND flash memory is allocated to be an SLC cache memory if the NAND flash memory is in the early phase of its life of service. A second portion of the NAND flash memory is allocated to be the SLC cache memory if the NAND flash memory is not in the early phase of its life of service. The second portion is smaller than the first portion. Finally, the data is written into the SLC cache memory according to the write command.

### BACKGROUND OF INVENTION

### 1. Field of Invention

The present invention relates to a NAND flash memory and, more particularly, to dynamic management of a cache memory of a NAND flash memory.

### 2. Related Prior Art

Flash memories can be classified as single-level chip (“SLC”) flash memories and multiple-level chip (“MLC”) flash memories. MLC flash memories include triple-level chip (“TLC”) flash memories. In comparison with a TLC flash memory, an SLC flash memory allows data to be written thereinto fast because the data can be written into the SLC flash memory in a burst-write mode. Hence, an SLC flash memory can be used as a cache memory. However, the density of data stored in an SLC cache memory is smaller than that of a TLC flash memory. Hence, a NAND flash memory is often configured to include an SLC cache memory and a TLC flash memory in an attempt to reach a balance between the speed of writing and the density of storage.

Referring to FIG. 4, a host 10 is connected to a solid-state drive (“SSD”) 32. SSD 32 includes a NAND flash memory 34. NAND flash memory 34 is configured to include an SLC cache memory 36 and a TLC flash memory 38. Conventionally, the size of space for storage of data in SLC cache memory 36 and that of TLC flash memory 38 are fixed.

According to a conventional method for operating NAND flash memory 34, data are written into SLC cache memory 36 in a burst-write mode. Then, immediately before SLC cache memory 36 runs out of space for storage of data, the data are transferred into TLC flash memory 38 from SLC cache memory 36.

However, the space for storage of data in SLC cache memory 36 is only a small portion of NAND flash memory 34 since the space for storage of data in NAND flash memory 34 is limited and because of over-provision. In practice, the space for storage of data in SLC cache memory 36 is about 3% of that of NAND flash memory 34. Hence, the burst-write mode can only last for a short period of time before the speed of writing of data into the NAND flash memory 34 (TLC flash memory 38 in particular) considerably drops. Hence, speed of writing of data often drops considerably during the transfer of large files or the execution of benchmark tools.

The present invention is therefore intended to obviate or at least alleviate the problems encountered in prior art.

### SUMMARY OF INVENTION

It is the primary objective of the present invention to provide a method for dynamically managing a NAND flash memory.

To achieve the foregoing objective, the method includes the step of receiving a write command from a host. The write command includes data to be stored in the NAND flash memory. Then, it is determined whether if the NAND flash memory has passed an early phase of its life of service. A first portion of the NAND flash memory is allocated to be an SLC cache memory if the NAND flash memory is still in the early phase of its life of service. A second portion of the NAND flash memory is allocated to be the SLC cache memory if the NAND flash memory has passed the early phase of its life of service. The second portion is smaller than the first portion. Finally, the data is written into the SLC cache memory according to the write command.

Other objectives, advantages and features of the present invention will be apparent from the following description referring to the attached drawings.

### BRIEF DESCRIPTION OF DRAWINGS

The present invention will be described via detailed illustration of the preferred embodiment referring to the drawings wherein:

FIG. 1 is a block diagram of a host and a solid state drive according to the preferred embodiment of the present invention;

FIG. 2 is a block diagram of a method for dynamically managing the solid state drive shown in FIG. 1;

FIG. 3 is a chart of the performance of the solid state drive shown in FIG. 1 versus a conventional solid state drive; and

FIG. 4 is a block diagram of a host and a conventional solid state drive.

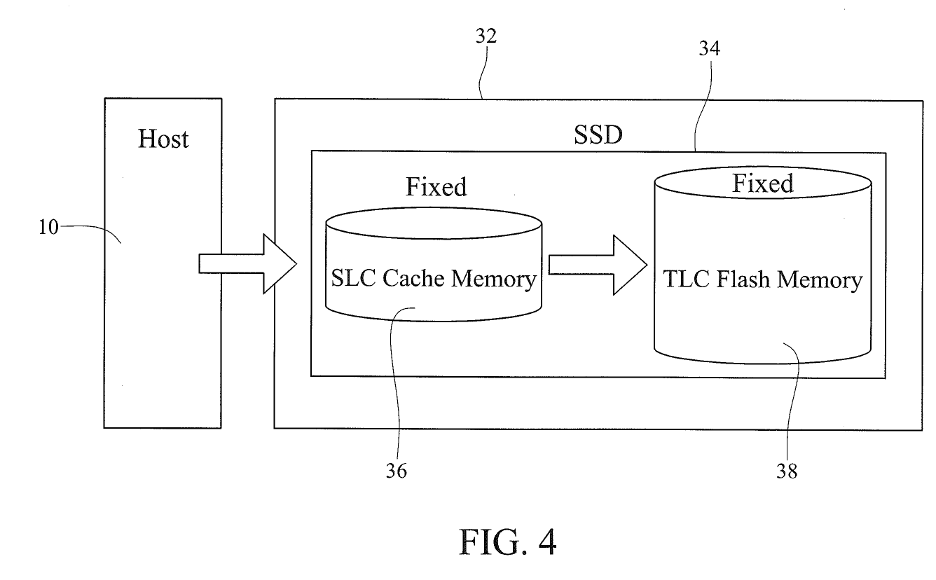

### DETAILED DESCRIPTION OF PREFERRED EMBODIMENT

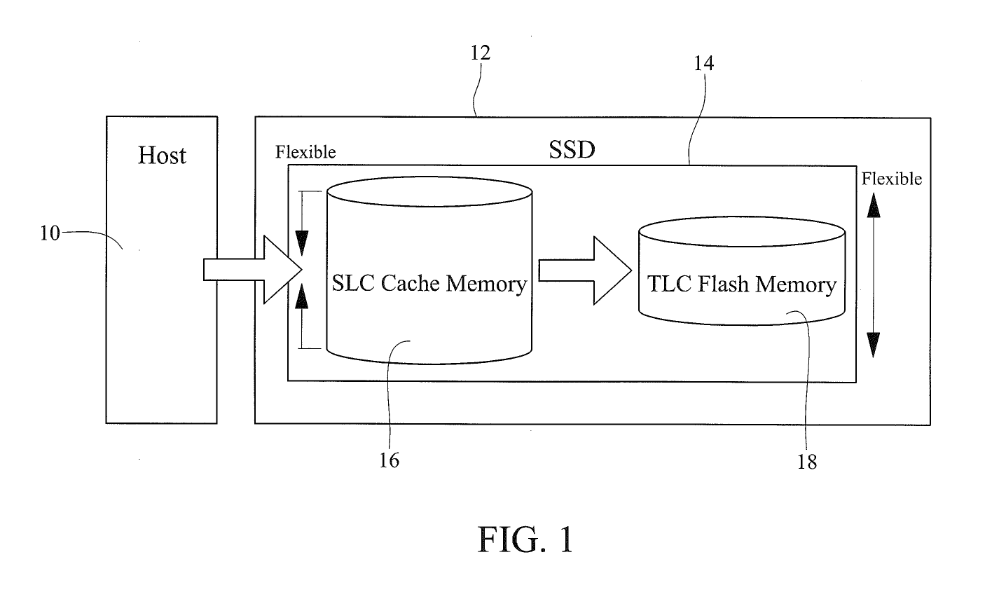

Referring to FIG. 1, a host 10 is electrically connected to a solid-state drive (“SSD”) 12. SSD 12 includes a NAND flash memory 14. NAND flash memory 14 is configured to include a SLC cache memory 16 and a TLC flash memory 18. In a method according to the preferred embodiment of the present invention, the size of space for storage of data in SLC cache memory 16 and that of TLC flash memory 18 are managed dynamically. Hence, the size of space for storage of data of SLC cache memory 16 and that of TLC flash memory 18 are adjustable.

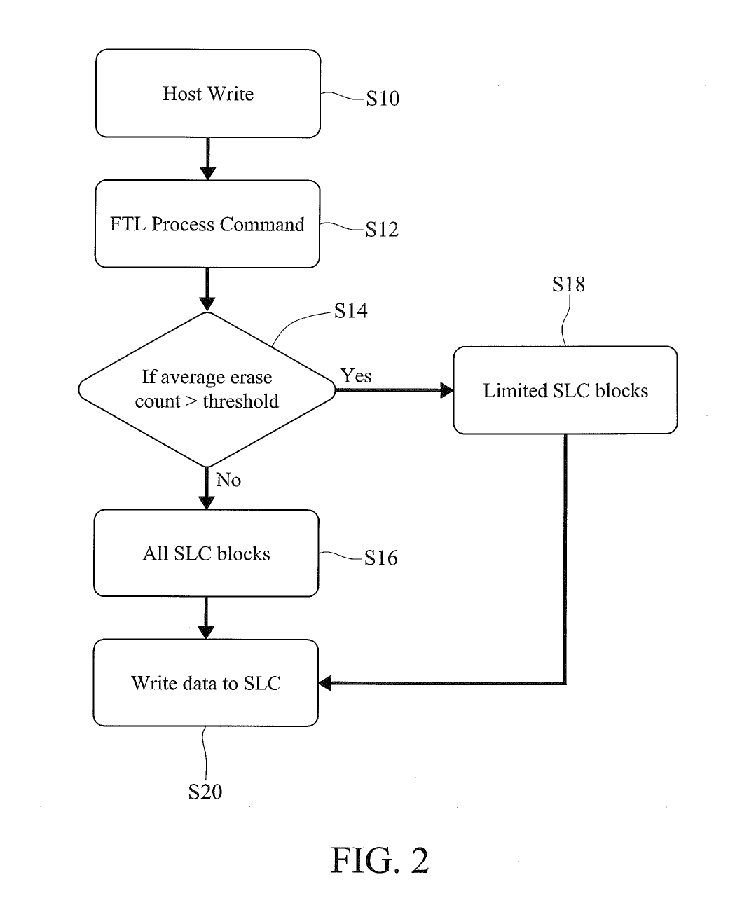

Referring to FIG. 2, the method according to the preferred embodiment of the present invention will be described in detail.

At S10, host 10 provides a write command. The write command includes data to be stored in SSD 12.

At S12, a flash translation layer (“FTL”) is used to process the write command, accordingly produce a backend (“BE”) command, and send the BE command to a BE.

At S14, the BE determines whether if an average erase count (“AEC”) is larger than a predetermined threshold. The process goes to S18 if the AEC is larger than the threshold, or goes to S16 if otherwise.

At S16, the size of space for storage of data in SLC cache memory 16 is set to be about 33% of that of NAND flash memory 14. Then, the process goes to 20.

At S18, the size of space for storage of data in SLC cache memory 16 is set to be about 1% of that of NAND flash memory 14. Then, the process goes to 20.

At S20, the BE writes the data into SLC cache memory 16. The data are written into SLC cache memory 16 in a burst-write mode.

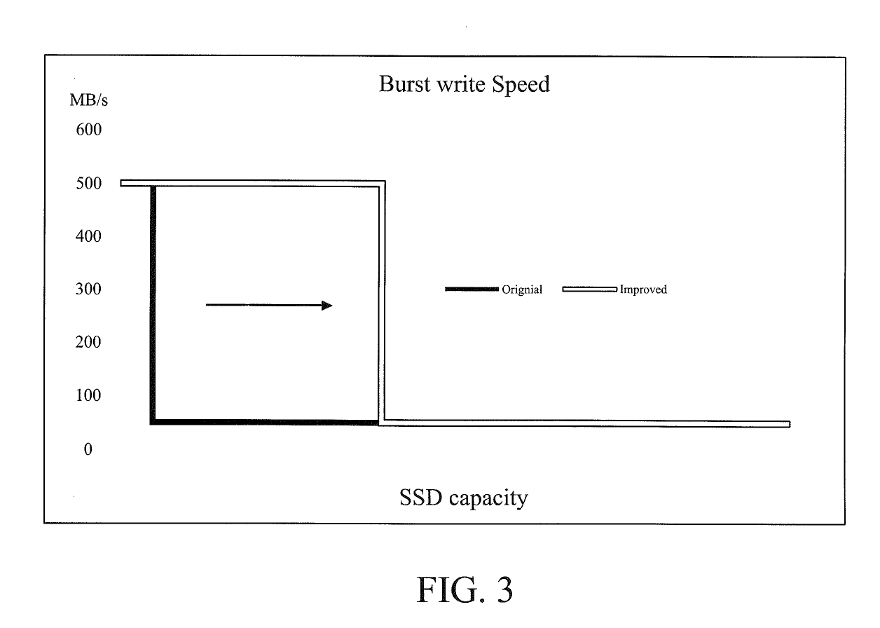

Referring to FIG. 3, the writing of the data in the burst-write mode lasts for a relatively long period of time because the size of space for storage of data in SLC cache memory 16 is relatively large if the size of space for storage of data in SLC cache memory 16 is set to be about 33% of that of NAND flash memory 14. The writing of the data in the burst-write mode lasts for a relatively short period of time because the size of space for storage of data in SLC cache memory 16 is relatively small if the size of space for storage of data in SLC cache memory 16 is set to be about 1% of that of NAND flash memory 14.

In the above-described method, S14 is executed to determine whether if SSD 12 (NAND flash memory 14 in particular) has passed an early phase of its life of service. SSD 12 is in an early phase of its life of service if the AEC is not larger than the threshold. Accordingly, SSD 12 can continue to serve for a long period of time. Hence, it is reasonable to use SSD 12 as much as possible, and allocate about 33% of the size of space for storage of data in NAND flash memory 14 to be that of SLC cache memory 16. SSD 12 has passed the early phase of its life of service if the AEC is larger than the threshold. Accordingly, SSD 12 can only continue to serve for a short period of time. Hence, it is reasonable to use SSD 12 as little as possible, and allocate about 1% of the size of space for storage of data in NAND flash memory 14 to be that of SLC cache memory 16. The dynamic management of NAND flash memory 14 is intended to reach a balance between the speed and the life of solid-state drive 12.

The present invention has been described via the illustration of the preferred embodiment. Those skilled in the art can derive variations from the preferred embodiment without departing from the scope of the present invention. Therefore, the preferred embodiment shall not limit the scope of the present invention defined in the claims.

1. A method for dynamically managing a NAND flash memory (14) comprising the steps of:
receiving a write command from a host (10), wherein the write command includes data to be stored in the NAND flash memory (14);
determining whether if the NAND flash memory (14) has passed an early phase of its life of service;
allocating a first portion of the NAND flash memory (14) to be an SLC cache memory (16) if the NAND flash memory (14) is still in the early phase of its life of service;
allocating a second portion of the NAND flash memory (14) to be an SLC cache memory (16) if the NAND flash memory (14) has passed the early phase of its life of service, wherein the second portion is smaller than the first portion; and
writing the data into the SLC cache memory (16) according to the write command.

2. The method according to claim 1, wherein the step of determining whether if the NAND flash memory (14) has passed an early phase of its life of service comprising the step of determining whether if an average erase count is larger than a pre-determined threshold.

3. The method according to claim 1, further comprising the step of using a flash translation layer to process the write command before the step of determining whether if the NAND flash memory (14) has passed an early phase of its life of service.

4. The method according to claim 1, wherein the first portion of the NAND flash memory (14) is 33% of the NAND flash memory (14).

5. The method according to claim 1, wherein the second portion of the NAND flash memory (14) is 1% of the NAND flash memory (14).
